(19) United States
(12) Patent Application Publication
(10) Pub. No.: US 2025/0351422 A1
(43) Pub. Date: Nov. 13, 2025

(54) FILTER FINS IN A GATE CONNECTOR REGION BETWEEN TRANSISTORS FOR SIGNAL FILTERING

(71) Applicant: Taiwan Semiconductor Manufacturing Company, Ltd., Hsin-Chu (TW)

(72) Inventors: Yi-Hong Wang, Taichung City (TW); Hui-Hsuan Kung, Taichung City (TW); Tien Yu Chu, Taichung City (TW); Chih-Hsiao Chen, Taichung City (TW); Yi-Chen Li, Taichung City (TW)

(21) Appl. No.: 19/277,162

(22) Filed: Jul. 22, 2025

Related U.S. Application Data
(63) Continuation of application No. 18/421,176, filed on Jan. 24, 2024.
(60) Provisional application No. 63/520,714, filed on Aug. 21, 2023.

(51) Int. Cl. H10D 30/62; H10D 84/85

(52) U.S. Cl. CPC H10D 30/6211; H10D 30/6219; H10D 84/853

(57) ABSTRACT

A semiconductor structure includes a first circuit area having first fin active regions extending lengthwise along a first direction, each of the first fin active regions includes first channel regions; a second circuit area having second fin active regions extending lengthwise along the first direction, each of the second fin active regions includes second channel regions; a gate connector area between and separating the first and the second circuit areas, the gate connector area having filter fins extending lengthwise along the first direction; and a gate structure extending across the first circuit area, the gate connector area, and the second circuit area along a second direction over the first and second channel regions and the filter fins. A portion of the gate structure in the gate connector area has a greater resistivity than portions of the gate structure in the first and the second circuit areas.

### PRIORITY DATA

This is a continuation application of U.S. patent application Ser. No. 18/421,176, filed Jan. 24, 2024, which claims the benefit of U.S. Provisional Application No. 63/520,714, filed Aug. 21, 2023, each of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, signal coupling between adjacent transistors become more pronounced. Therefore, a dummy area between adjacent transistors should have sufficient spacing for proper isolation. In the dummy area, there are no active devices. However, common gate structures may still span across the dummy area and extending to connect and land on multiple channel regions across multiple transistor devices. The dummy area thus may also be referred to as a gate connector area or region. As such, gate input signals to one transistor device may also couple to the gate of adjacent transistor devices or even further transistor devices beyond the adjacent transistor devices. In some applications, these gate input signals may have signal components or loss not suitable for passing through to adjacent transistor devices or to other transistor devices sharing a same gate structure. In other words, these gate input signals may require conditioning and filtering for improved performance.

Therefore, although existing structures for dummy areas between adjacent transistors have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a semiconductor structure exemplified by a circuit diagram showing a gate signal, according to an embodiment of the present disclosure.

FIG. 2 illustrates a gate signal going through a low-pass filter, according to an embodiment of the present disclosure.

FIGS. 3A-3B illustrates a semiconductor structure having filter fins, according to an embodiment of the present disclosure.

FIGS. 4A-4B illustrates a semiconductor structure having filter fins, according to another embodiment of the present disclosure.

FIG. 4C illustrates a capacitance-voltage (C-V) characteristics graph for MOSFET devices, according to an embodiment of the present disclosure.

FIGS. 5A-5B illustrates a semiconductor structure having filter fins, according to another embodiment of the present disclosure.

FIGS. 6A-6B illustrates a semiconductor structure having filter fins, according to another embodiment of the present disclosure.

FIGS. 7A-7D illustrates a semiconductor structure having filter fins, according to another embodiment of the present disclosure.

FIGS. 8A-8D illustrates a semiconductor structure having filter fins, according to another embodiment of the present disclosure.

FIGS. 9A-9B and 10A-10C illustrates a semiconductor structure having filter fins, according to another embodiment of the present disclosure.

FIGS. 11A-11D illustrates a semiconductor structure having filter fins, according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximately,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, can be understood to be within +/−10% between the compared features. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor structures having filter fins for gate signal filtering. Specifically, the filter fins are incorporated in a dummy area between transistor areas. The dummy area does not have active transistor devices while the transistor areas have active transistor devices. The dummy area may be referred to as a gate connector area because gate structures span across this area to land on transistor devices in adjacent the transistor areas. However, since the dummy area in the present embodiments includes filter fins to perform signal filtering, the dummy area is herein referred to as a filter circuit area. The present disclosure describes input gate signals in one transistor area being filtered by the structural configuration in the filter circuit area, such that only low frequency signal passes through to the adjacent transistor area but high frequency signals and loss are absorbed by the filter fins in the filter circuit area and routed towards the substrate. The filter fins are configured to result in resistance and capacitance change to the gate structure, which creates path resistance and parasitic capacitance to form a low pass filter. Other ways to affect the low pass filter may include changing dimensions and materials for the metal gate in the filter circuit area, the filter fins, or both. Additionally, or alternatively, adding a top layer-dielectric over the filter fins, the metal gate, and/or adding metal contacts over the filter fins or the metal gate may provide additional signal paths for signal filtering.

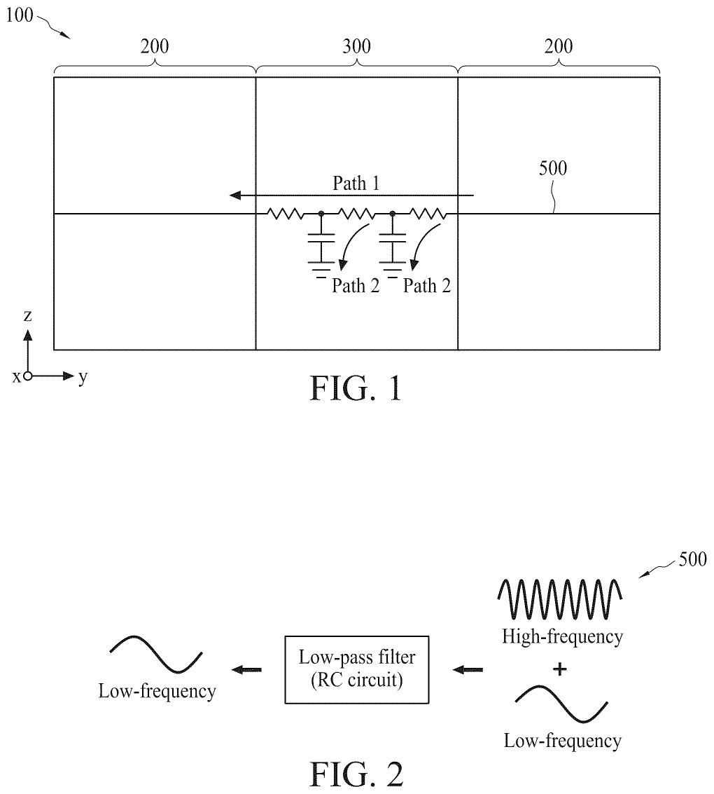

FIG. 1 illustrates a semiconductor structure 100 exemplified by a circuit diagram showing an input gate signal 500. The semiconductor structure 100 includes a filter circuit area 300 (also referred to as a dummy area or a gate connector area) sandwiched between transistor circuit areas 200 along the y direction (i.e., lengthwise direction of metal gate structures). In the present embodiment, the transistor circuit areas 200 include active transistor devices, and the gate connector area 300 is free of active transistor devices. The structural details of the semiconductor structure 100 in the transistor circuit and gate connector areas 200 and 300 will be explained in the later figures.

As shown in FIG. 1, the filter circuit area 300 functions as a filter circuit providing different signal paths. In an embodiment, an input gate signal 500 (e.g., input gate voltage) is applied to a gate structure in the rightmost transistor circuit area 200. As shown in path 1, the input gate signal 500 may travel across the filter circuit area 300 to the leftmost transistor circuit area 200 through the series resistors. As shown in path 2, the input gate signal 500 may be redirected to ground through the parallel capacitors. Specifically, when the input gate signal 500 is a low frequency signal, the input gate signal 500 will travel through path 1 due to the parallel capacitors in path 2 functioning as open circuits in low frequency mode. And when the input gate signal 500 is a high frequency signal, the input gate signal 500 will travel through path 2 due to the parallel capacitors in path 2 functioning as short circuits to ground in high frequency mode. This is because the current flows through a path with lower impedance. Therefore, low frequency signals tend to pass resistors but not capacitors, and high frequency signals tends to pass capacitors but not resistors. In other words, the filter circuit functions as a low-pass filter that filters out high frequency signals and allowing low frequency signals to pass. In this way, only low-frequency gate signals will bias the gate structure in the leftmost transistor circuit area 200, while high frequency signals are filtered out in the filter circuit area 300.

FIG. 2 complements FIG. 1 and illustrates an input gate signal 500 going through a low-pass filter such as the one described above with respect to FIG. 1. As shown, the input gate signal 500 may include both high-frequency and low-frequency components. The high-frequency components may include spikes and signal noise which is filtered out in the low-pass filter. And the low frequency components pass through the low-pass filter to power the gates in the adjacent transistor circuit area 200. As such, the input gate signal 500 is conditioned and filtered for improved performance.

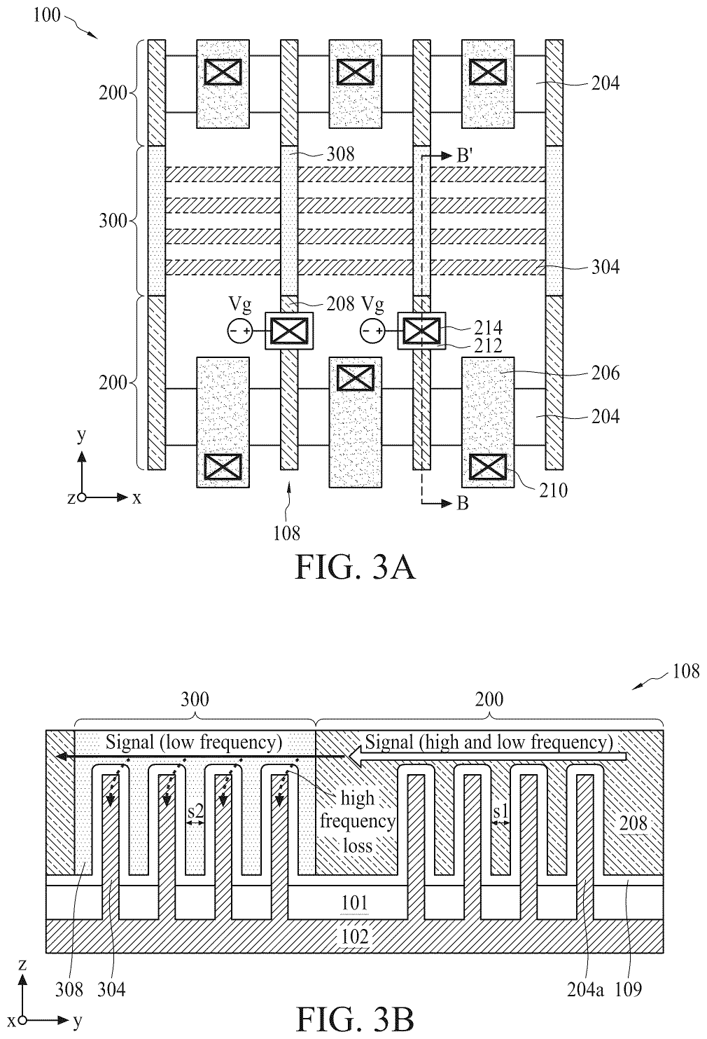

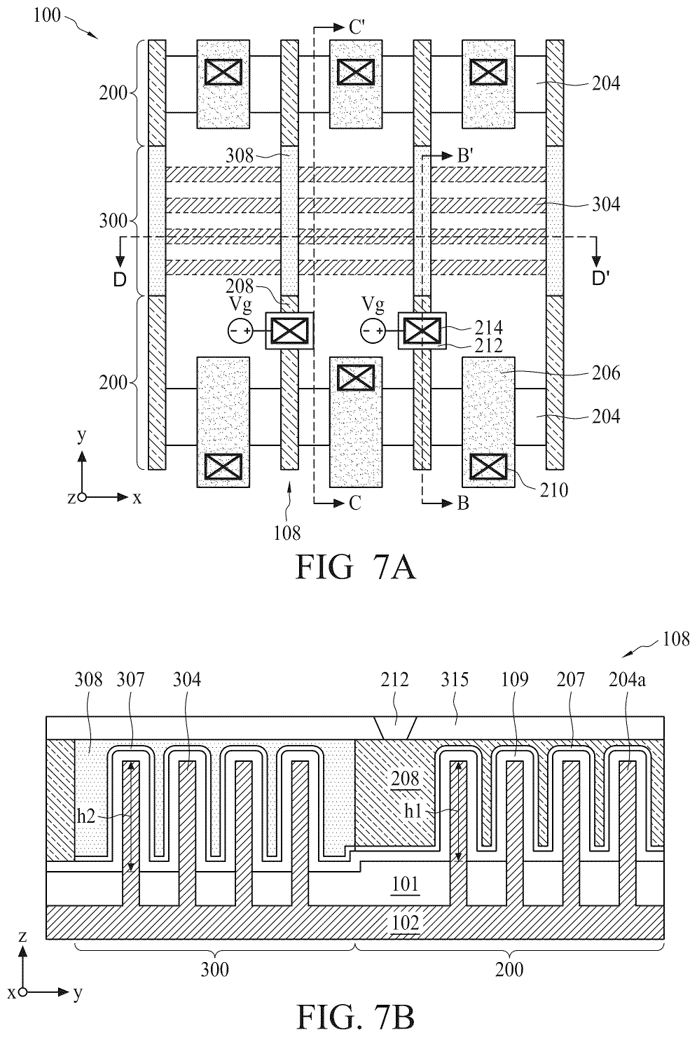

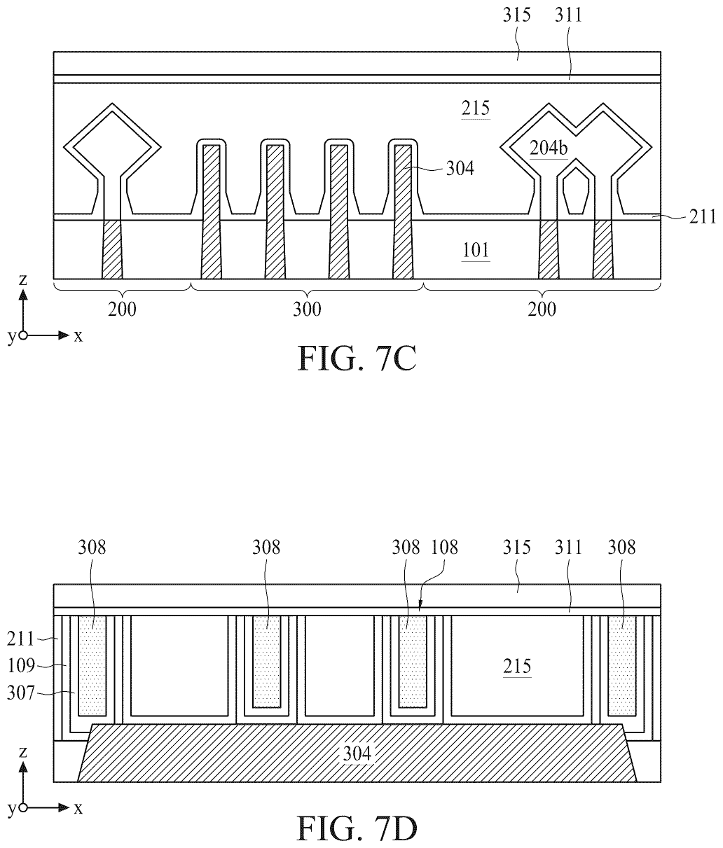

FIG. 3A illustrates a top view of a semiconductor structure 100 having filter fins 304, according to an embodiment of the present disclosure. As shown, FIG. 3A illustrates a filter circuit area 300 between adjacent transistor circuit areas 200, which structurally corresponds to the transistor and filter circuit areas 200 and 300 as described with respect to FIG. 1. Each of the transistor circuit areas 200 includes one or more fin active regions 204 protruding from a substrate (e.g., substrate 102 in FIG. 3B). The substrate 102 may be a silicon (Si) substrate, or a substrate having other semiconductor materials such as germanium (Ge), silicon carbide (SiC), silicon germanium (SiGe), or diamond. The one or more fin active regions 204 may include Si, Ge, SiGe, SiC, gallium arsenide (GaAs), gallium nitride (GaN), carbon (C), indium (In), or combinations thereof. FIG. 3A only shows one fin active region 204 in each transistor circuit area 200 for purposes of simplicity. The one fin active region 204 may represent more than one fin active region 204, such as four fin active regions 204, as illustrated in FIG. 3B. Each of the fin active regions 204 extends lengthwise in the x direction and may be separated from each other by an isolation structure (e.g., isolation structure 101 in FIG. 3B). Each of the fin active regions 204 may include a channel region 204a (see e.g., FIG. 3B) between source/drain features 204b (see e.g., FIG. 7C). Source/drain features 204b are disposed in source/drain region(s) adjacent channel regions 204a, and the source/drain region(s) may refer to a source or a drain, individually or collectively dependent upon the context. The channel regions 204a are defined by portions of the fin active regions 204 directly underneath a gate structure 108, and the source/drain features 204b are defined by portions of the fin active regions 204 adjacent the channel regions 204a. Source/drain contacts 206 are disposed over the source/drain features 204b. And source/drain vias 210 are disposed over the source/drain contacts 206. The source/drain contacts 206 and source/drain vias 210 are conductive features that electrically connect the source/drain features 204b to higher level metal interconnects.

Still referring to FIG. 3A, the filter circuit area 300 includes one or more filter fins 304 protruding from the substrate 102. The filter circuit area 300 is also referred to as a dummy area 300 or a gate connector area 300. The filter fins 304 extends lengthwise in the x direction and may be separated from each other by the isolation structure 101. The filter fins 304 may include similar materials as the fin active regions 204. Note that the filter fins 304 do not have distinctive channel regions or source/drain features because they do not form transistor devices. Instead, they act as filter devices to condition input gate signals.

Still referring to FIG. 3A, gate structures 108 are disposed over and span across the adjacent transistor circuit areas 200 and the filter circuit area 300 therebetween. Specifically, the gate structures 108 extends lengthwise in the y direction directly over channel regions 204a of the fin active regions 204 and directly over portions of the filter fins 304. Each of the gate structure 108 includes a transistor gate portion 208 in the transistor circuit areas 200 and a filter gate portion 308 in the filter circuit area 300. As explained in more detail with respect to FIG. 3B, the transistor gate portion 208 and the filter gate portion 308 differ in resistivity due to various factors. Each of the gate structures includes a gate dielectric layer and a gate electrode disposed on the gate dielectric layer. The segments of the gate electrode in the filter gate portion 308 are different from the segments of the gate electrode in the transistor gate portion 208 in composition. Particularly, the segments of the gate electrode in the filter gate portion 308 have a resistivity greater than the segments of the gate electrode in the transistor gate portion 208. Gate contacts 212 are disposed over the transistor gate portions 208 of the gate structure 108. And gate vias 214 are disposed over the gate contacts 212. The gate vias 214 are electrically connected to a gate supply voltage Vg that supplies an input gate voltage signal.

FIG. 3B illustrates a cross-sectional view of the semiconductor structure 100 in FIG. 3A cut along the line B-B′. In the cross sectional view, a portion of a gate structure 108 is shown spanning across four filter fins 304 and four fin active regions 204 (or specifically four channel regions 204a). In an embodiment, the filter fins 304 and the fin active regions 204 have the same or similar fin widths along the y direction. The filter fins 304 and the fin active regions 204 are separated from each other by an isolation structure 101. The isolation structure 101 provides isolation between adjacent fin structures and may be a shallow trench isolation (STI) layer. The isolation structure 101 may include silicon oxide, silicon oxynitride, fluorine-doped silicate glass (FSG), a low-k dielectric, combinations thereof, and/or other suitable materials. In the present embodiment, the isolation structure 101 is disposed over the semiconductor substrate 102, and each of the filter fins 304 and fin active regions 204 protrudes from the substrate 102 to above the isolation structure 101. As illustrated in FIG. 3B, each of the gate structure 108 includes a gate dielectric 109 conformally disposed over the channel regions 204a and over the filter fins 304. The gate dielectric 109 may include a high-k dielectric material such as a material having a dielectric constant greater than silicon oxide (k≈3.9). The high-k dielectric material may include a metal oxide such as hafnium oxide, zirconium oxide, aluminum oxide, or a combination thereof. In some embodiments, the high-k dielectric material includes oxygen and La, Ze, Zn, Y, Ba, N, or a combination thereof. Each of the gate structure 108 also includes a gate electrode over the gate dielectric 109. For purposes of simplicity, the transistor gate portions 208 and the filter gate portion 308 may be referred to as the gate electrode of the respective gate portions. In the present embodiment, the filter gate portion 308 exhibits a higher resistivity than the transistor gate portions 208. This is to provide the necessary resistance and capacitance in the filter circuit area 300 for filtering high frequency signals.

Still referring to FIG. 3B, the higher resistivity in the filter gate portions 308 may be achieved in multiple ways. In an embodiment, the higher resistivity is achieved by packing the filter fins 304 more densely in the filter circuit area. By packing the filter fins 304 closer to each other, the gate electrode over the filter fins results in higher resistivity due to surface contact and fill-in effect. To achieve this, in an embodiment, a spacing s2 between filter fins 304 is smaller than a spacing s1 between fin active regions 204. This may be achieved by packing in more filter fins 304 in the filter circuit area 300 compared to the fin active regions 204 in the transistor circuit areas 200 (e.g., 2 fin active region 204 in each transistor circuit areas 200 and 4 or more filter fins 304 in the filter circuit area 300). In an embodiment, the spacing s2 ranges between about 20 nm to about 22 nm. Modifying the spacing s2 is made possible due to design flexibility in the filter circuit area 300, while spacing parameters in the transistor circuit area 200 are usually fixed. In another embodiment, the spacing s1 and s2 is the same, and the higher resistivity is achieved by changing the work function or the gate electrode material in the filter gate portion 308. For example, the filter gate portion 308 includes a higher resistance metal material than that of the transistor gate portions 208. In an embodiment, the transistor gate portions 208 includes Ag, Au, Al, Rh, W, Mo, Zn, Co, Ru, Nb, or combinations thereof, and the filter gate portions 308 includes Ti, TiN, brass, phosphor bronze, cast steel, a metal compound, or a combination thereof. In further embodiments, higher resistivity may be achieved by combinations of the embodiments described herein.

Still referring to FIG. 3B, a gate voltage Vg (e.g., input gate signal 500) is applied to the transistor gate portion 208 (e.g., through the gate contact 212 and gate via 214 in FIG. 3A). The gate contact 212 and the gate via 214 is not shown in FIG. 3B for the sake of simplicity. The gate voltage Vg may include signals having both high and low frequency. As the signal travels from the transistor gate portion 208 across the filter gate portion 308, high frequency signals such as high frequency noise bypasses the gate structure and is absorbed into the filter fins 304 and towards the substrate 102 through capacitive coupling. In an embodiment, the substrate 102 is connected to ground. Meanwhile, low frequency signals pass through the gate electrode of the filter gate portion 308 to an adjacent transistor circuit area 200. As illustrated here, the filter fins 304 and the filter gate portion 308 forms the low-pass circuit as described with respect to FIGS. 1-2. Specifically, the filter gate portion 308 separated from the filter fins 304 by the gate dielectric 109 forms parallel capacitors shorting to ground for high frequencies (e.g., path 2). And the filter gate portion 308 having higher resistance metal forms the series resistance path for low frequencies (e.g., path 1). The low frequency gate signals then power the gates for adjacent transistor devices.

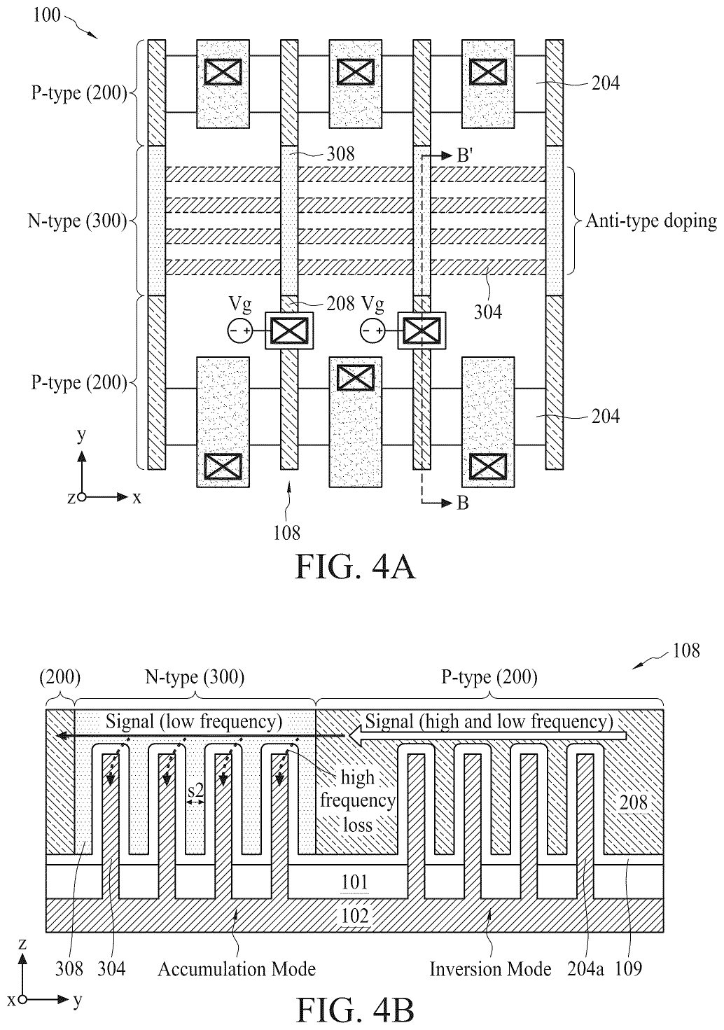

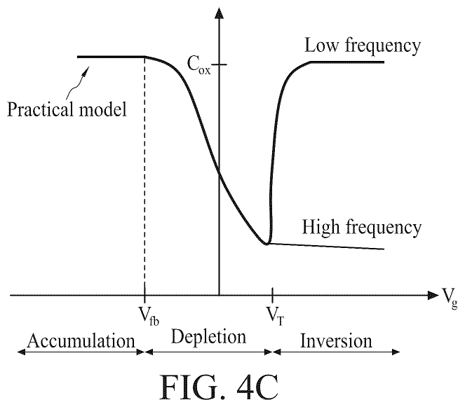

FIGS. 4A-4B illustrates a semiconductor structure 100 having filter fins 304, according to another embodiment of the present disclosure. FIGS. 4A-4B is similar to FIGS. 3A-3B and the similar features will not be described again for the sake of brevity. To facilitate high capacitance for high frequency filtering, FIGS. 4A-4B illustrates an anti-type doping scheme to ensure that during operation, there is high capacitance in the filter circuit area 300 and low capacitance in the transistor circuit areas 200. The anti-type doping scheme includes generating doping profile where the filter fins 304 are doped with an opposite-type dopant from the channel regions 204a of the fin active regions 204. For example, in the embodiment shown, the transistor circuit areas 200 have p-type wells (or p-type substrate regions) for the channel regions 204a to form n-type transistor devices. As such, the filter circuit area 300 is doped with an n-type dopant to achieve anti-type doping. In this way, during operation, the fin active regions 204 and the filter fins 304 are in different modes of operation (inversion versus accumulation).

To illustrate the mechanism of anti-type doping, FIG. 4C illustrates a capacitance-voltage (C-V) characteristics graph for MOSFET devices. During operation (when gate is turned on), transistor devices usually operate under inversion mode. Under inversion mode, high frequency results in lower capacitance which is desirable for transistor devices in the transistor circuit areas 200 because these areas should not have extraneous parasitic capacitance. However, it is desirable for higher capacitance in the filter circuit area 300 for achieving low-pass filter effect. If the filter fins 304 are doped with a same-type dopant as in the transistor circuit areas 200, the filter fins 304 would operate under inversion mode like in the channel regions 204a, where at high frequency the capacitance reduces. If this is the case, the effect of the low-pass filter is degraded. By doping the filter fins 304 with an opposite-type dopant, high capacitance is maintained because when the transistor devices are in inversion mode, the filter fins are in accumulation mode. As shown in FIG. 4C, in accumulation mode, no matter the frequency, the capacitance stays high.

Now referring to FIG. 4B, when gate signal propagates during operation, the p-type doped transistor circuit area 200 operates under inversion mode, and the n-type doped filter circuit area 300 operates under accumulation mode. As such, high capacitance is maintained when high frequency is filtered through the filter fins 304 while low frequency passes through to an adjacent transistor circuit area 200. N-type dopants may include carbon, phosphorous, arsenic, other n-type dopant, or combinations thereof. P-type dopants may include boron, other p-type dopant, or combinations thereof. Note that for each fin active regions 204, the channel regions 204a and the source/drain features 204b are oppositely doped. As such, in some embodiments, the filter fins 304 are doped with a same-type dopant as that of the source/drain features 204b. In an embodiment, the channel regions 204a are doped with boron, the source/drain features 204b are doped with arsenic or phosphorous, and the filter fins 304 are doped with arsenic or phosphorous. FIGS. 4A-4B illustrates when the transistor circuit areas 200 are p-type doped and the filter circuit area is n-type doped. In other embodiments, the transistor circuit areas 200 are n-type doped and the filter circuit area is p-type doped.

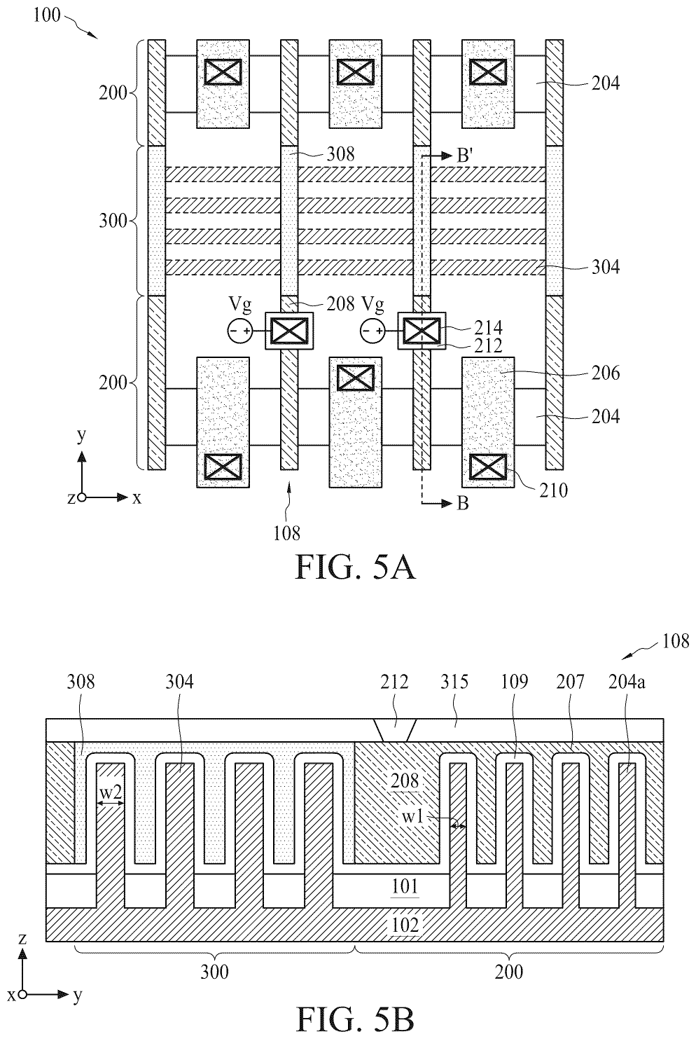

FIGS. 5A-5B illustrates a semiconductor structure 100 having filter fins 304, according to another embodiment of the present disclosure. FIGS. 5A-5B is similar to FIGS. 3A-3B and the similar features will not be described again for the sake of brevity. In the embodiment of FIGS. 5A-5B, the filter fins 304 are formed wider than the channel regions 204a of the fin active regions 204. Referring to FIG. 5B, the filter fins 304 have a width w2 along the y direction, the channel regions 204a of the fin active regions 204 have a width w1 along the y direction, and the width w2 is greater than the width w1. In an embodiment, a ratio of w2 to w1 is about 1 to 3. The wider filter fins 304 results in a greater interface with the gate dielectric 109, thereby providing a greater capacitance for improved gate signal filtration. In other respects, FIG. 5B may be similar to FIG. 3B in terms of spacing between fins and gate metal materials in the transistor circuit area 200 versus the filter circuit area 300. FIG. 5B further shows a gate contact 212 disposed directly above the transistor gate portions 208 of the gate structure 108. The gate contact 212 is electrically connected to a gate supply voltage Vg that supplies an input gate voltage signal (e.g., through a gate via 214). The gate contacts 212 is embedded in an interlayer dielectric (ILD) layer 315 disposed over the gate structure 108. The ILD layer 315 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

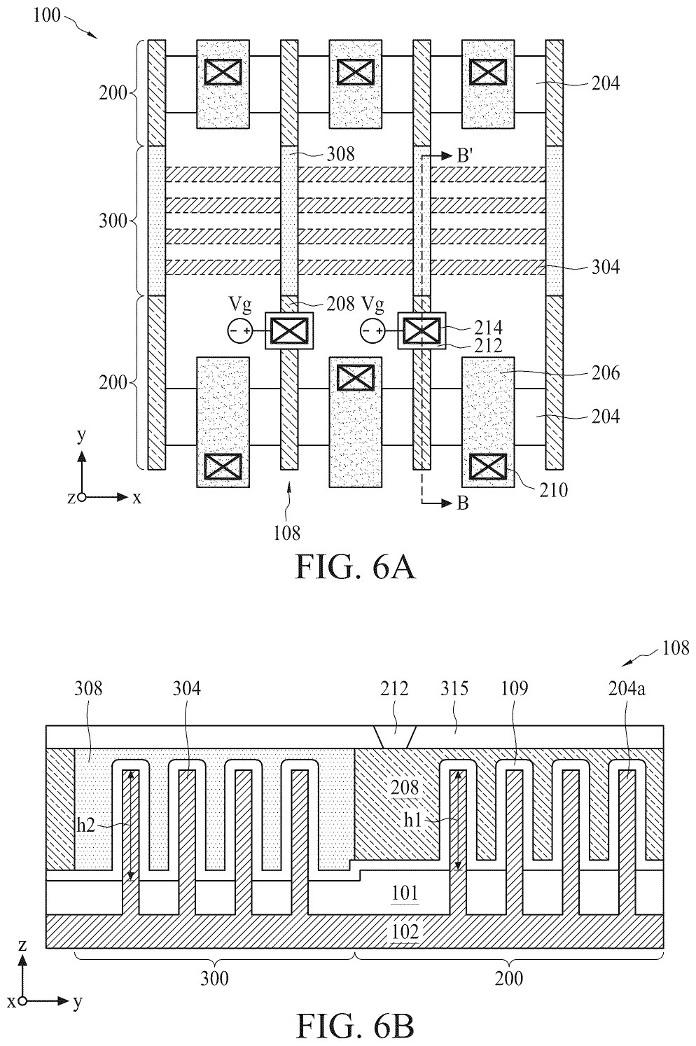

FIGS. 6A-6B illustrates a semiconductor structure 100 having filter fins 304, according to another embodiment of the present disclosure. FIGS. 6A-6B is similar to FIGS. 3A-3B and the similar features will not be described again for the sake of brevity. In the embodiment of FIGS. 6A-6B, the filter fins 304 are formed to have a greater effective height than the fin active regions 204. The effective height is defined to be a height protruding above a top surface of the isolation structure 101. Referring to FIG. 5B, the filter fins 304 have an effective height h2 along the z direction, the channel regions 204a of the fin active regions 204 have an effective height h1 along the z direction, and the effective height h2 is greater than the effective height h1. The greater effective height h2 results in a greater interface between the filter fins 304 and the gate dielectric 109, thereby providing a greater capacitance for improved gate signal filtration. Note that although the effective height h2 is greater than the effective height h1, top surfaces of the filter fins 304 is substantially coplanar with top surfaces of the channel regions 204a. That is, the filter fins 304 and the fin active regions 204 protrude above the substrate 102 at about the same height. The effective height is made different due to height differences of the isolation structure 101 in the transistor circuit area 200 versus the filter circuit area 300. As shown, portions of the isolation structure 101 in the filter circuit area 300 and surrounding the filter fins 304 is formed shallower in the z direction than portions of the isolation structure in the transistor circuit area 200. In other words, top surface of the isolation structure 101 in the transistor circuit area 200 is above top surface of the isolation structure 101 in the filter circuit area 300. FIG. 6B further shows a gate contact 212 disposed directly above the transistor gate portions 208 of the gate structure 108. The gate contact 212 is electrically connected to a gate supply voltage Vg that supplies an input gate voltage signal (e.g., through a gate via 214). The gate contacts 212 is embedded in an interlayer dielectric (ILD) layer 315 disposed over the gate structure 108. The ILD layer 315 may include a dielectric material that includes for example, silicon oxide, fused silica, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

FIGS. 7A-7D illustrates a semiconductor structure 100 having filter fins 304, according to another embodiment of the present disclosure. FIGS. 7A-7B is similar to FIGS. 6A-6B and the similar features will not be described again for the sake of brevity. In the embodiment of FIGS. 7A-7B, additional work function metal layers 207 and 307 may be incorporated as part of the gate structure 108. Referring to FIG. 7B, a work function metal layer 207 is disposed between the gate dielectric 109 and the transistor gate portion 208, and a work function metal layer 307 is disposed between the gate dielectric 109 and the filter gate portion 308. The added work function metal layers 207 and 307 provide additional tuning of gate voltage as desired. The work function metal layers 207 and 307 includes a conductive layer having a metal or metal alloy with proper work function such that the corresponding transistor device (e.g., nFET or pFET) is enhanced for its device performance. The work function metal layer 207 and 307 may include a metal selected from but not restricted to the group of titanium aluminum nitride (TiAlN), titanium aluminum (TiAl), tungsten aluminide (WAl), titanium nitride (TiN), tantalum nitride (TaN), ruthenium (Ru), molybdenum (Mo), tungsten (W), platinum (Pt), aluminum (Al), or combinations thereof; and may be deposited by CVD, PVD, and/or other suitable process. The work function metal layer 307 may be different in composition for a pFET versus an nFET. In an embodiment, the work function metal layers 207 and 307 include different metal materials. In an embodiment, the work function metal layer 307 includes a higher resistance metal material than that of the work function metal layer 207. In further embodiments, higher resistivity may be achieved by combinations of the embodiments described herein.

FIG. 7C illustrates a cross-sectional view of FIG. 7A cut along the line C-C′ in the y direction. The line C-C′ cuts across one or more source/drain features 204b of the fin active regions 204 and one or more of the filter fins 304. The source/drain features 204b include epitaxial features while the filter fins 304 are free of epitaxial features. The epitaxial features may be formed to have an expanding profile to form a diamond shape over a top portion of the source/drain feature 204b. In some embodiments, the epitaxial features are merged along the y direction between adjacent fin active regions 204. The epitaxial features may be doped with n-type dopants and/or p-type dopants. In some embodiments, for n-type transistors, epitaxial features include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors, epitaxial features include silicon germanium or germanium and can be doped with boron, other p-type dopant, or combinations thereof (for example, forming Si:Ge:B epitaxial source/drain features). As shown, the filter fins 304 in the filter circuit area 300 are free of epitaxial features and are sandwiched between the source/drain features 204b in different transistor circuit areas 200. An etch stop layer 211 may be conformally deposited over sidewall and top surfaces of the source/drain features 204b and the filter fins 304. In an embodiment, the etch stop layer 211 includes silicon nitride, silicon oxynitride, or silicon carbonitride. An interlayer dielectric (ILD) layer 215, which may include the etch stop layer 211, is disposed over and surrounding the source/drain features 204b and the filter fins 304. The ILD layer 215 may include similar materials as the ILD layer 315 previously described. An etch stop layer 311 having similar materials as the etch stop layer 211 is disposed over the ILD layer 215, and the ILD layer 315 is disposed over the etch stop layer 311. In an embodiment, the ILD layers 215 and 315 include different dielectric materials as that of the etch stop layers 211 and 311.

FIG. 7D illustrates a cross-sectional view of FIG. 7A cut along the line D-D′ in the x direction. The line D-D′ cuts along a filter fin 304 and across multiple gate structures 108 (specifically the filter gate portions 308 of the gate structures 108). As shown, for each gate structure 108, a gate dielectric 109 is disposed over the filter fin 304, a work function metal layer 307 is disposed over the gate dielectric 109, and a filter gate portion 308 is disposed over the work function metal layer 307. Each gate structure 108 is separated from each other in the x direction by the etch stop layer 211 and the ILD layer 215. As shown, top surfaces of the ILD layer 215 and the gate structures 108 are substantially coplanar. The etch stop layer 311 is disposed over the gate structures 108 and the ILD layer 215. The ILD layer 315 is disposed over the etch stop layer 311.

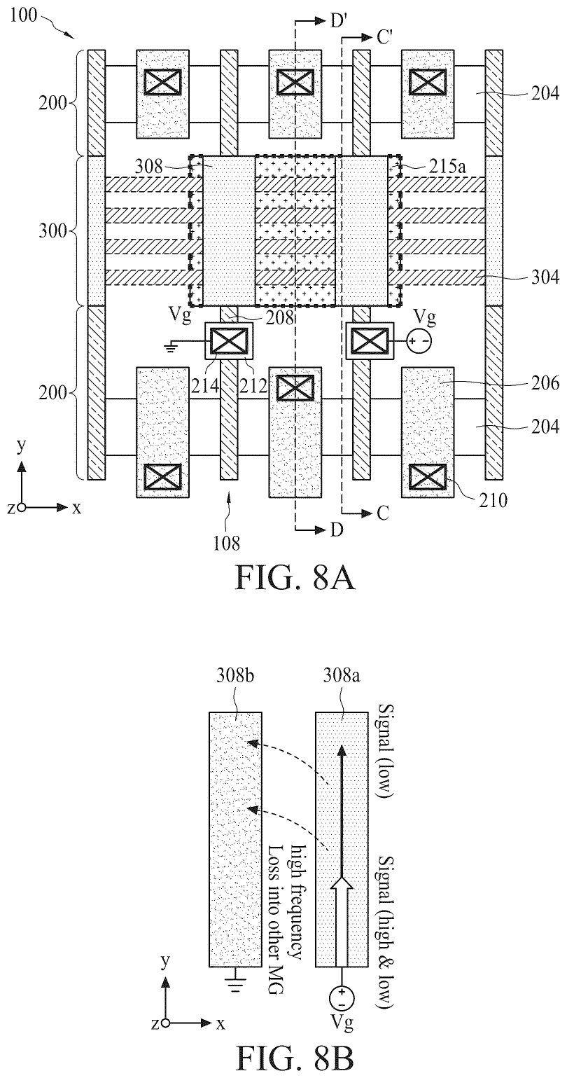

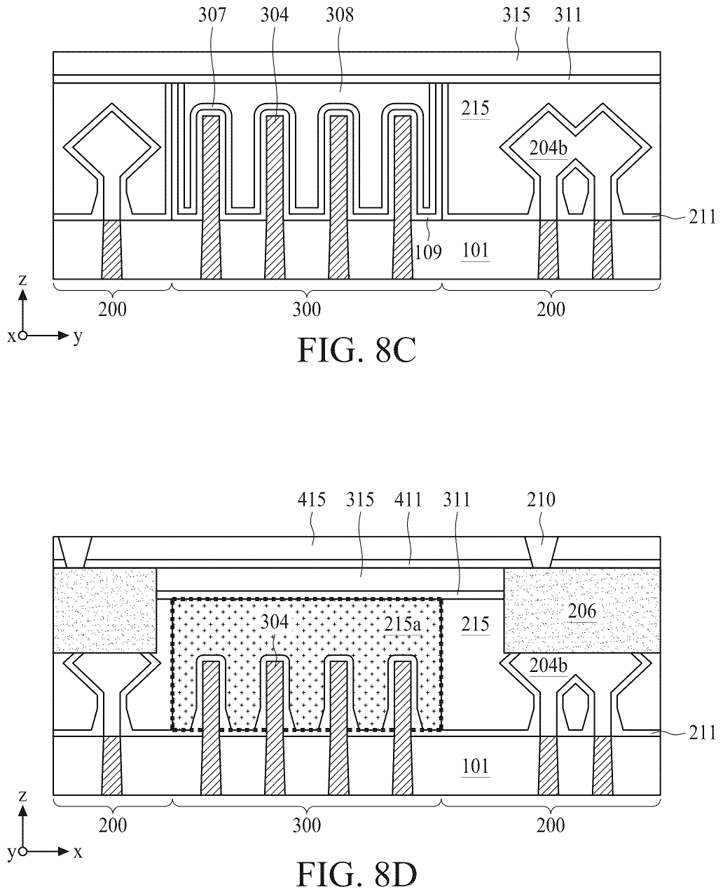

FIGS. 8A-8D illustrates a semiconductor structure 100 having filter fins 304, according to another embodiment of the present disclosure. Similar features described in previous embodiments will not be repeated here for the sake of brevity. In previous embodiments, the gate signal filtration was through the filter fins 304 and vertically downward to substrate 102, which is then grounded. Here, in combination with the filter fins 304, gate signal filtration may be also achieved in the lateral direction (i.e., x direction) across adjacent filter gate portions 308. Adjacent filter gate portions 308 are part of adjacent gate structures 108, and the adjacent gate structures 108 may extend lengthwise over different channel regions 204a of different portions of the fin active regions 204. In this embodiment, a capacitive filter is formed between two adjacent filter gate portions 308 and a high-k dielectric layer (e.g., high-k ILD layer 215a) therebetween. As described with respect to FIG. 7D, the dielectric layer between filter gate portions 308 may be the ILD layer 215. To facilitate high capacitance, a portion of the ILD layer 215 surrounding and between the two adjacent filter gate portions 308 is replaced with a high-k ILD layer 215a. The high-k ILD layer 215a has a higher dielectric constant than that of the ILD layer 215. The high-k ILD layer 215a may include a metal oxide such as hafnium oxide, zirconium oxide, aluminum oxide, or a combination thereof. In some embodiments, the high-k dielectric material includes oxygen and La, Ze, Zn, Y, Ba, N, or a combination thereof. To further facilitate high capacitance, the two adjacent filter gate portions 308 are widened in the x direction such that the adjacent filter gate portions 308 are closer to each other. As shown, a lateral spacing between adjacent filter gate portions 308 in the x direction is smaller than a lateral spacing between adjacent transistor gate portions 208. In an embodiment, the widened filter gate portions 308 has a width greater than 1.1 times a width of the transistor gate portion 208. Note that to allow for gate signal filtration in the lateral direction from gate to gate, one of the gate structures 108 is provided with an input gate voltage Vg and the other gate structure 108 is grounded. For example, as shown, a first gate contact 212 is disposed over the transistor gate portions 208 of a first gate structure 108. And a first gate via 214 is disposed over the first gate contact 212. The first gate via 214 is electrically connected to a gate supply voltage Vg that supplies an input gate voltage signal. A second gate contact 212 is disposed over the transistor gate portions 208 of a second adjacent gate structure 108. And a second gate via 214 is disposed over the second gate contact 212. The second gate via 214 is electrically connected to ground. In an embodiment, there are cut metal gate features (not shown) that separates portions of the gate structure 108 (e.g., the left gate structure 108 shown to be grounded) from other portions of the gate structure 108. These other portions of the gate structure 108 are not grounded and remain available for transistor operation.

FIG. 8B illustrates the mechanism of high frequency gate signal filtering in the horizontal direction. FIG. 8B illustrates two adjacent filter gate portions 308 of two adjacent gate structures 108. The two adjacent filter gate portions 308 are labeled as a first filter gate portion 308a and a second filter gate portion 308b. An input gate signal having high and low frequencies is provided to the first filter gate portion 308a via the input gate voltage Vg. As the gate signal travels in the y direction, high frequency signals such as high frequency loss travels horizontally in the x direction into the second filter gate portion 308b due to the capacitive filter described above. These high frequency signals are then grounded via a ground connection routed to the second filter gate portion 308b. Meanwhile, the low frequency signals pass and continues to propagate in the y direction. In addition to high frequency filtering from gate structure 108 to filter fins 304 to ground (as illustrated in FIG. 3B), FIG. 8B illustrates that high frequency filtering is also possible from a first gate structure 108 to a second gate structure 108 to ground.

FIG. 8C illustrates a cross-sectional view of FIG. 8A cut along the line C-C′ in the y direction. The line C-C′ cuts across one or more source/drain features 204b of the fin active regions 204 and one or more of the filter fins 304. Note that the line C-C′ also cuts along a filter gate portion 308 since the filter gate portion 308 is widened in this embodiment. FIG. 8C is similar to FIG. 7C and the similar features are not described again for the sake of brevity. The difference here is that the filter gate portion 308 of a gate structure 108 is disposed over the filter fins 304. As shown, the gate dielectric 109 surrounds the filter fins 304, the work function metal layer 307 is disposed over the gate dielectric 109, and the filter gate portion 308 is disposed over the work function metal layer 307. Here, both the filter fins 304 and the filter gate portion 308 is sandwiched between source/drain features 204b of different transistor circuit areas 200. Further, the filter gate portion 308 is embedded within the ILD layer 215 and having a top surface coplanar with the top surface of the ILD layer 215. The etch stop layer 311 is disposed over top surfaces of the ILD layer 215 and the filter gate portion 308. Note that in the embodiment shown, a sidewall of the gate dielectric 109 may interface with a sidewall of the etch stop layer 211.

FIG. 8D illustrates a cross-sectional view of FIG. 8A cut along the line D-D′ in the y direction. The line D-D′ cuts across one or more source/drain features 204b of the fin active regions 204 and one or more of the filter fins 304. Note that the line D-D′ also cuts across the high-k ILD layer 215a and the source/drain contacts 206 and source/drain vias 210. FIG. 8D shows similar features as FIG. 8C because the cross-sectional cut is also across source/drain features 204b and filter fins 304. However, this cross-section shows the high-k ILD layer 215a disposed over the filter fins 304, which acts as the dielectric layer of the capacitive filter described above. The high-k ILD layer 215a is embedded and surrounded by the ILD layer 215, which includes a dielectric having a lower dielectric constant than that of the high-k ILD layer 215a. Also in this view, source/drain contacts 206 are disposed over the source/drain features 204b, and source/drain vias 210 are disposed over the source/drain contacts 206. An etch stop layer 411 is disposed over the source/drain contacts 206 and over the ILD layer 315, and an ILD layer 415 is disposed over the etch stop layer 411. The etch stop layer 411 may include similar materials as the etch stop layers 211 and 311, and the ILD layer 415 may include similar materials as the ILD layers 215 and 315. In an embodiment, the ILD layers 215, 315, and 415 include different dielectric materials as that of the etch stop layers 211, 311, and 411. The source/drain contacts 206 penetrates through the ILD layer 315 and the etch stop layer 311 to land on the source/drain features 204b. The source/drain vias 210 penetrates through the ILD layer 415 and the etch stop layer 411 to land on the source/drain contacts 206.

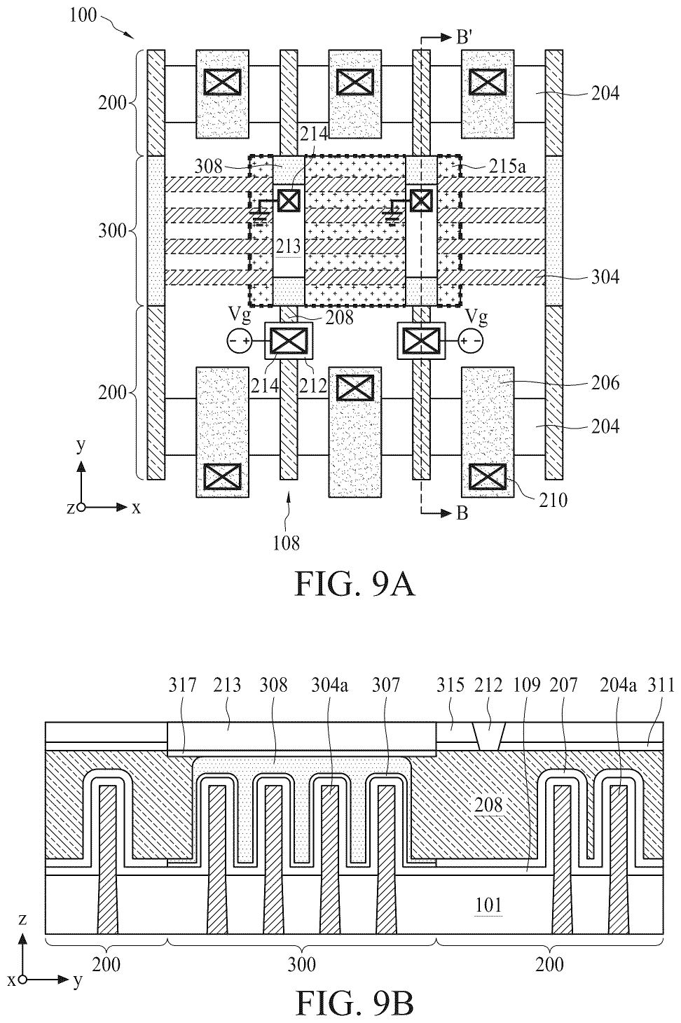

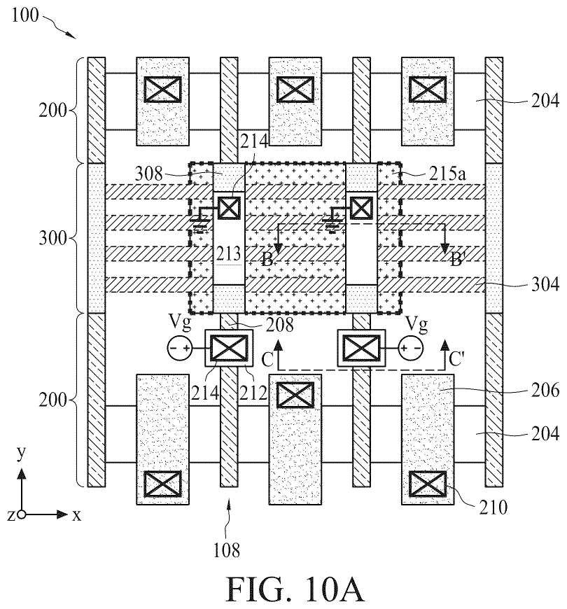

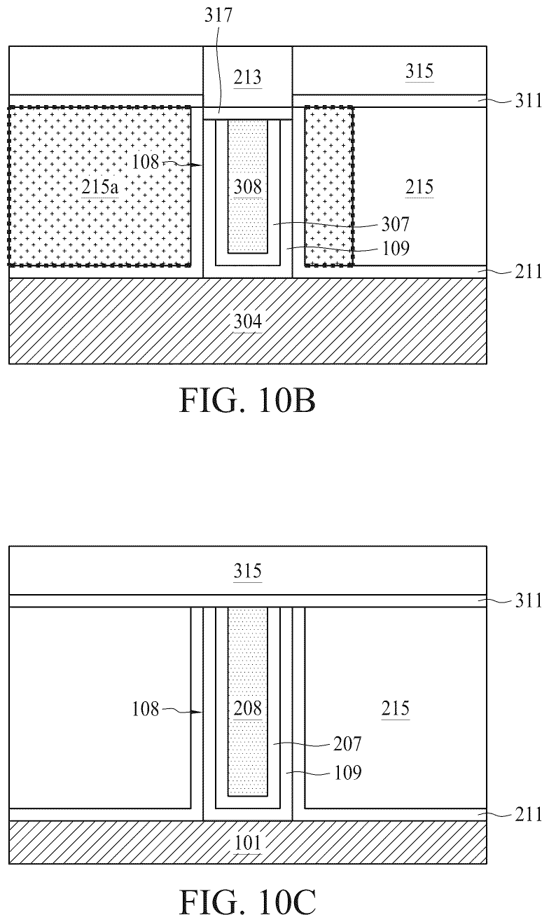

FIGS. 9A-9B and 10A-10C illustrates a semiconductor structure 100 having filter fins 304, according to another embodiment of the present disclosure. Similar features described in previous embodiments will not be repeated here for the sake of brevity. In previous embodiments, high frequencies of gate signals may be filtered out downwards through the filter fins 304 into the substrate 102 and/or sideways from one gate structure 108 to another adjacent gate structure 108. Here, another way to achieve gate signal filtration is in the upwards direction (i.e., positive z direction) towards a metal feature 213 that is routed to ground. For example, as shown, a gate via 214 connected to a ground node is disposed over the metal feature 213. In this embodiment, a capacitive filter is formed by a high-k dielectric layer 317 between a filter gate portion 308 of a gate structure 108 and a metal feature 213. Note that FIG. 9A also illustrate the high-k ILD layer 215a surrounding two adjacent filter gate portions 308, although in some embodiments the high-k ILD layer 215a omitted.

FIG. 9B illustrates a cross-sectional view of FIG. 9A cut along the line B-B′ in the y direction. The line B-B′ cuts along a gate structure 108 across one or more fin active regions 204 and one or more filter fins 304. FIG. 9B is similar to FIGS. 3B-7B as described above and the similar features are not described again for the sake of brevity. As shown, the gate structure 108 includes a gate dielectric 109 conformally deposited over the channel regions 204a of the fin active regions 204, work function metal layers 207 over the gate dielectric 109 in the transistor circuit areas 200, work function metal layer 307 over the gate dielectric 109 in the filter circuit area 300, gate electrode of transistor gate portion 208 over the work function metal layers 207, and gate electrode of filter gate portion 308 over the work function metal layer 307. Further, a high-k dielectric layer 317 is disposed over and landing on the filter gate portion 308, and a metal feature 213 is disposed over and landing on the high-k dielectric layer 317. The high-k dielectric layer 317 isolates the filter gate portion 308 from the metal feature 213. The high-k dielectric layer 317 may include similar materials as the gate dielectric 109 and/or the high-k ILD layer 215a. The high-k dielectric layer 317 may be laterally surrounded by the transistor gate portions 208, and top surfaces of the high-k dielectric layer 317 and the transistor gate portions 208 may be substantially coplanar. In an embodiment, the high-k dielectric layer 317 has a thickness greater than 0.8 nm. In other embodiments, the high-k dielectric layer 317 is replaced with a silicon oxide layer having a thickness greater than 1.4 nm. The metal feature 213 penetrates through the ILD layer 315 and the etch stop layer 311 to land on the high-k dielectric layer 317. The metal feature 213 is routed to ground through for example a gate via 214 disposed thereon (not shown in FIG. 9B but shown in FIG. 9A). In this configuration, as input gate signal having high and low frequencies travels in the y direction, high frequency signals such as high frequency loss travels downwards in the negative z direction through the filter fins 304 towards the substrate 102 and also upwards in the positive z direction through the high-k dielectric layer 317 towards the metal feature 213.

Now referring to FIGS. 10A-10C, additional cross-sectional views are provided. FIG. 10A reproduces FIG. 9A, and FIGS. 10B-10C illustrate cross-sectional views of FIG. 10A cut along the lines B-B′ and C′C′ respectively. Note that the similarly labeled features may correspond to previously labeled features already described. FIG. 10B shows a gate structure 108 having a gate dielectric 109 over a filter fin 304, a work function metal layer 307 over the gate dielectric 109, and a gate electrode (i.e., a filter gate portion 308) over the work function metal layer 307. The gate structure 108 is laterally surrounded by a high-k ILD layer 215a, which is disposed over an etch stop layer 211 over the filter fin 304. An ILD layer 215 may be disposed adjacent the high-k ILD layer 215a and over the etch stop layer 211. A high-k dielectric layer 317 is disposed over the gate structure 108 and between the high-k ILD layer 215a. The high-k dielectric layer 317 may be formed by a metal pullback process by first selectively etching back the gate structure 108 to form a trench, then filling the trench with a high-k material and performing a planarization process. As such, a top surface of the high-k dielectric layer 317 may be coplanar with a top surface of the high-k ILD layer 215a and the ILD layer 215. An etch stop layer 311 is disposed over the high-k dielectric layer 317, the high-k ILD layer 215a, and the ILD layer 215. An ILD layer 315 is disposed over the etch stop layer 311. A metal feature 213 penetrates through the ILD layer 315 and the etch stop layer 311 to land on the high-k dielectric layer 317. FIG. 10C shows a different portion of the gate structure 108 in FIG. 10B, the gate structure 108 having a gate dielectric 109 over an isolation structure 101, a work function metal layer 207 over the gate dielectric 109, and a gate electrode (i.e., a transistor gate portion 208) over the work function metal layer 207. The gate structure 108 is laterally surrounded by the ILD layer 215. The etch stop layer 311 is disposed over the ILD layer 215 and over the gate structure 108. The ILD layer 315 is disposed over the etch stop layer 311.

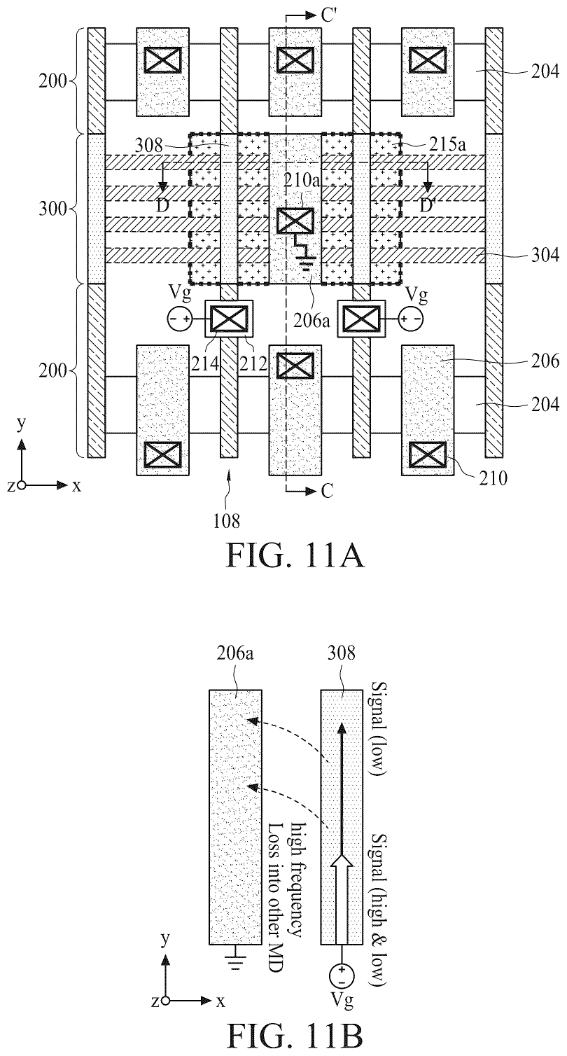

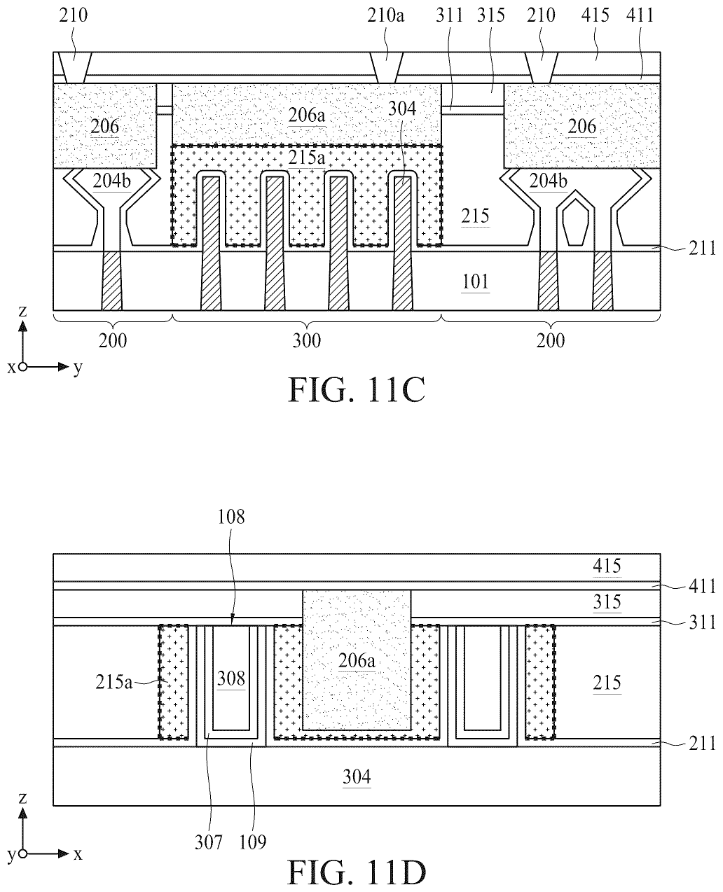

FIGS. 11A-11D illustrates a semiconductor structure 100 having filter fins 304, according to another embodiment of the present disclosure. Similar features described in previous embodiments will not be repeated here for the sake of brevity. In previous embodiments, high frequencies may be filtered out downwards through the filter fins 304 into the substrate 102, and/or sideways from one gate structure 108 to another adjacent gate structure 108, and/or upwards through the high-k dielectric layer 317 towards the metal feature 213. Here, another way to achieve high frequency gate signal filtration is from a filter gate portion 308 of a gate structure 108 to an adjacent metal contact 206a (in the x direction) that is routed to ground. For example, as shown, a contact via 210a connected to a ground node is disposed over the metal contact 206a. In this embodiment, a capacitive filter is formed by a filter gate portion 308, a metal contacts 206a, and a high-k dielectric layer (e.g., high-k ILD layer 215a) therebetween. As described with respect to FIG. 7D, the dielectric layer therebetween may be the ILD layer 215. To facilitate high capacitance, the ILD layer 215 or a portion thereof surrounding and between the two adjacent filter gate portions 308 is replaced with a high-k ILD layer 215a.

Referring to FIG. 11A, the metal contact 206a is disposed over the filter fins 304 and extending in the y direction across the filter circuit area 300. The metal contact 206a is disposed between two adjacent filter gate portions 308 in the x direction. In an embodiment, the metal contact 206a may be aligned with the source/drain contacts 206 in the transistor circuit areas 200 in the y direction. In an embodiment, a spacing between the metal contact 206a and an adjacent filter gate portion 308 is less than half a spacing between adjacent gate structures 108 (or specifically adjacent transistor gate portions 208) along the x direction.

FIG. 11B illustrates the mechanism of high frequency gate signal filtering in the horizontal direction between a filter gate portion 308 and an adjacent metal contact 206a. An input gate signal having high and low frequencies is provided to the filter gate portion 308 via the input gate voltage Vg. As the gate signal travels in the y direction, high frequency signals such as high frequency loss travels horizontally in the x direction into the metal contact 206a due to the capacitive filter described above. These high frequency signals are then grounded via a ground connection routed to the metal contact 206a. Meanwhile, the low frequency signals pass and continue to propagate in the y direction. FIG. 11B illustrates that high frequency filtering is also possible from a first gate structure 108 to an adjacent metal contact 206a to ground.

FIG. 11C illustrates a cross-sectional view of FIG. 11A cut along the line C-C′ in the y direction. The line C-C′ cuts across one or more source/drain features 204b of the fin active regions 204 and one or more of the filter fins 304. Note that the line C-C′ also cuts across the metal contact 206a disposed over the filter fins 304. FIG. 11C is similar to FIG. 8D and the similar features are not described again for the sake of brevity. The difference here is that a metal contact 206a penetrates through the ILD layer 315, the etch stop layer 311, and a portion of the high-k ILD layer 215a to land on a top surface of the high-k ILD layer 215a. In FIG. 11C, the metal contact 206a does not contact the filter fins 304. However, in other embodiments, the metal contact 206a may directly contact and land on the filter fins 304. A contact via 210a penetrates through the ILD layer 415 and the etch stop layer 411 to land on the metal contact 206a. The contact via 210a may be electrically connected to ground.

FIG. 11D illustrates a cross-sectional view of FIG. 11A cut along the line D-D′ in the x direction. The line D-D′ cuts along a filter fin 304 across two adjacent filter gate portions 308 of two gate structures 108, and across the contact via 210a therebetween. FIG. 11D is similar to FIG. 7D and the similar features are not described again for the sake of brevity. The difference is the incorporation of the high-k ILD layer 215a laterally embedded between the ILD layer 215, where the high-k ILD layer 215a surrounds the filter gate portions 308 of the two adjacent gate structures 108 and also the metal contact 206a therebetween. In FIG. 11D, the metal contact 206a penetrates through the ILD layer 315, the etch stop layer 311, and a portion of the high-k ILD layer 215a but does not contact the filter fin 304. However, in other embodiments, the metal contact 206a may directly contact and land on the filter fin 304.

The present disclosure illustrates various embodiments of effectuating a gate signal low-pass filter by utilizing a filter circuit area 300 having filter fins 304. The filter circuit area 300 is a gate connector area having filter gate portions 308 that connects transistor gate portions 208 in the transistor circuit areas 200. The filter fins 304 filter out high frequency gate signals while allowing low frequency signals to pass. Note that the various embodiments described herein may stand alone to achieve gate signal filtering or they may be combined with each other for tailored signal conditioning.

Although not limiting, the present disclosure offers advantages for incorporating filter fins in a gate connector area between transistor circuit areas. One example advantage is filtering high frequency signals or loss through the filter fins and into the substrate so that gate signal is conditioned when powering an adjacent transistor area. Another example advantage is adjusting the interface area between gate dielectric and the filter fins such as changing width and height to increase capacitance for improved high frequency filtering. Another example advantage is doping the filter fins with an opposite-type dopant as the transistor channels for keeping high capacitance of the filter fins in accumulation mode. Another example advantage is incorporating high-k dielectric materials and metal features in the filter fin regions for alternative paths of signal filtering such as from gate structure to gate structure, from gate structure to an adjacent metal contact, or from gate structure to a metal feature above the gate structure. Other example advantages includes incorporating different gate metal materials (e.g., work function layers) in the gate connector area versus the transistor circuit areas to tune resistivity.

One aspect of the present disclosure pertains to a semiconductor structure. The semiconductor structure includes a first circuit area having first fin active regions extending lengthwise along a first direction over a substrate, each of the first fin active regions includes first channel regions between first source/drain features; a second circuit area having second fin active regions extending lengthwise along the first direction over the substrate, each of the second fin active regions includes second channel regions between second source/drain features; a gate connector area between and separating the first and the second circuit areas, the gate connector area having filter fins extending lengthwise along the first direction over the substrate; and a gate structure extending across the first circuit area, the gate connector area, and the second circuit area along a second direction perpendicular to the first direction, the gate structure is disposed over the first and second channel regions and over the filter fins. The gate structure includes a gate dielectric over top and side surfaces of the first fin active regions, the second fin active regions, and the filter fins. A portion of the gate structure in the gate connector area has a greater resistivity than portions of the gate structure in the first and the second circuit areas.

In an embodiment, the first fin active regions are spaced apart from each other by a first spacing along the second direction, the filter fins are spaced apart from each other by a second spacing along the second direction, and the first spacing is greater than the second spacing.

In an embodiment, the first fin active regions have a first width along the second direction, the filter fins have a second width along the second direction, and the second width is greater than the first width.

In an embodiment, the first and second channel regions are doped with a first dopant, the filter fins are doped with a second dopant, and the first and second dopants are opposite type dopants.

In an embodiment, the semiconductor structure further includes an isolation structure over the substrate and surrounding the first fin active regions, the second fin active regions, and the filter fins. The first fin active regions have a first height protruding above a top surface of the isolation structure, the filter fins have a second height protruding above a top surface of the isolation structure, and the second height is greater than the first height.

In a further embodiment, the source/drain features of the first fin active regions include epitaxial features of the second dopant, where each of the filter fins are free of epitaxial features.

In an embodiment, the source/drain features of the first fin active region, the source/drain features of the second fin active region, and the filter fins are surrounded by an interlayer dielectric (ILD) layer. The ILD layer includes a first dielectric portion surrounding the source/drain features of the first and the second fin active regions, a second dielectric portion surrounding the filter fins, and the second dielectric portion has a greater dielectric constant than the first dielectric portion.

In a further embodiment, the first dielectric portion includes a dielectric material having a dielectric constant equal to or less than that of silicon oxide, and the second dielectric portion includes a metal oxide with a dielectric constant greater than that of silicon oxide.

In a further embodiment, the gate structure is a first gate structure, and the semiconductor structure further includes: a second gate structure adjacent the first gate structure along the first direction, the second gate structure extends across the first circuit area, the gate connector area, and the second circuit area along the second direction, and the second gate structure is disposed over third channel regions of the first and the second fin active regions and over the filter fins, where a portion of the second gate structure within the gate connector area has a greater resistivity than portions of the second gate structure within the first and the second circuit areas. The portion of the first and second gate structures within the gate connector area has a greater width along the first direction than the portions of the first and second gate structures within the first and the second circuit areas. The first gate structure is electrically connected to a gate voltage, and the second gate structure is electrically connected to ground.

In a further embodiment, the gate structure is a first gate structure, and the semiconductor structure further includes: a second gate structure adjacent the first gate structure along the first direction, the second gate structure extends across the first circuit area, the gate connector area, and the second circuit area along the second direction, and the second gate structure is disposed over third channel regions of the first and the second fin active regions and over the filter fins, where a portion of the second gate structure within the gate connector area has a greater resistivity than portions of the second gate structure within the first and the second circuit areas; and a metal feature between the first and the second gate structures along the first direction, the metal feature landing on the second portion of the ILD layer and isolated from the first and the second gate structures. The first or the second gate structures are electrically connected to a gate voltage, and the metal feature is electrically connected to ground.

In a further embodiment, the semiconductor structure further includes: a high-k dielectric layer landing on the portion of the gate structure within the gate connector area; and a metal feature landing on the high-k dielectric layer and isolated from the gate structure. The portion of the gate structure within the first circuit area is electrically connected to a gate voltage, and the metal feature is electrically connected to ground.

Another aspect of the present disclosure pertains to a semiconductor structure. The semiconductor structure includes a transistor area having fin active regions extending lengthwise along a first direction over a substrate, each of the fin active regions includes channel regions between source/drain features; a filter area adjacent the transistor area along a second direction perpendicular to the first direction, the filter area having filter fins extending lengthwise along the first direction over the substrate; and a gate structure having a gate dielectric and a gate fill metal over the gate dielectric, the gate structure extends across the transistor area and the filter area along the second direction, and the gate structure is disposed directly over the channel regions of the fin active regions and directly over the filter fins. The source/drain features of the fin active regions include epitaxial features, and the filter fins are free of epitaxial features.

In a further embodiment, the channel regions and the source/drain features have opposite type dopants. The channel regions have a first-type dopant, and the filter fins have a second-type dopant opposite the first-type dopant.

In a further embodiment, the gate structure includes a first gate portion within the transistor area and a second gate portion within the filter area, and the second gate portion has a greater resistivity than the first gate portion.

In a further embodiment, the first gate portion includes Ag, Au, Al, Rh, W, Mo, Zn, Co, Ru, Nb, or combinations thereof, and the second gate portion includes Ti, TiN, brass, phosphor bronze, cast steel, a metal compound, or a combination thereof.

In a further embodiment, the semiconductor structure further includes: a high-k dielectric layer landing on the second gate portion; and a metal feature landing on the high-k dielectric layer and isolated from the gate structure. The first gate portion is electrically connected to a gate voltage, and the metal feature is electrically connected to ground.

In a further embodiment, the semiconductor structure further includes: a high-k dielectric layer over and surrounding the filter fins; and a metal feature landing on the high-k dielectric layer and isolated from the gate structure. The first gate portion is electrically connected to a gate voltage, and the metal feature is electrically connected to ground.

Another aspect of the present disclosure pertains to a semiconductor structure. The semiconductor structure includes a transistor region having fin active regions extending lengthwise along a first direction over a substrate, each of the fin active regions includes channel regions between source/drain features; a filter region adjacent the transistor region along a second direction perpendicular to the first direction, the filter region having filter fins extending lengthwise along the first direction over the substrate; a first gate structure having a first gate dielectric and a first gate electrode over the first gate dielectric, the first gate structure extends across the transistor region and the filter region along the second direction, and the first gate structure is disposed over a first set of channel regions and filter fins; a second gate structure having a second gate dielectric and a second gate electrode over the second gate dielectric, the second gate structure extends across the transistor region and the filter region along the second direction, and the second gate structure is disposed over a second set of channel regions and filter fins; and an interlayer dielectric (ILD) layer having a first dielectric portion surrounding the source/drain features, a second dielectric portion surrounding the filter fins, and the second dielectric portion has a greater dielectric constant than the first dielectric portion.

In an embodiment, a spacing between the first gate structure and the second gate structure in the transistor region is a first spacing, a spacing between the first gate structure and the second gate structure in the filter region is a second spacing, and the first spacing is greater than the second spacing. The first gate structure is electrically connected to a gate voltage, and the second gate structure is electrically connected to ground.

In an embodiment, the semiconductor structure further includes: a metal feature between the first and the second gate structures along the first direction, the metal feature landing on the second dielectric portion of the ILD layer; and a source/drain contact landing on one of the source/drain features of the fin active regions. A top surface of the metal feature and the source/drain contact is substantially coplanar.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first circuit area having first active regions extending lengthwise along a first direction over a substrate, each of the first active regions includes first channel regions between first source/drain features;
a second circuit area having second active regions extending lengthwise along the first direction over the substrate, each of the second active regions includes second channel regions between second source/drain features;
a gate connector area between and separating the first and the second circuit areas, the gate connector area having filter fins extending lengthwise along the first direction over the substrate; and
a gate structure continuously extending across the first circuit area, the gate connector area, and the second circuit area along a second direction perpendicular to the first direction, the gate structure is disposed over the first and second channel regions and over the filter fins,
wherein the gate structure includes a gate dielectric over top and side surfaces of the first active regions, the second active regions, and the filter fins, and the filter fins have a greater width than each of the first and the second active regions along the second direction.

2. The semiconductor structure of claim 1, wherein the filter fins have a first width, the first and the second active regions have a second width, and a ratio of the first width to the second width ranges between about 1 to about 3.

3. The semiconductor structure of claim 1, wherein a first spacing between adjacent filter fins is substantially the same as a second spacing between adjacent first active regions or adjacent second active regions.

4. The semiconductor structure of claim 1, wherein a first spacing between adjacent filter fins is smaller than a second spacing between adjacent first active regions or adjacent second active regions.

5. The semiconductor structure of claim 1, wherein a portion of the gate structure in the gate connector area has a greater resistivity than portions of the gate structure in the first and the second circuit areas.

6. The semiconductor structure of claim 1,
wherein the gate structure in the first and the second circuit areas include a first gate electrode over the gate dielectric,
wherein the gate structure in the gate connector area includes a second gate electrode over the gate dielectric,
wherein the first and second gate electrodes include different materials.

7. The semiconductor structure of claim 6,
wherein the first gate electrode includes Ag, Au, Al, Rh, W, Mo, Zn, Co, Ru, Nb, or combinations thereof,
wherein the second gate electrode includes Ti, TiN, brass, phosphor bronze, cast steel, a metal compound, or a combination thereof.

8. The semiconductor structure of claim 1,
wherein the first and second channel regions are doped with a first dopant, the filter fins are doped with a second dopant, and the first and second dopants are opposite type dopants.

9. The semiconductor structure of claim 8,
wherein the first source/drain features of the first active regions include epitaxial features of the second dopant,
wherein each of the filter fins are free of epitaxial features.

10. The semiconductor structure of claim 1, further comprising:
an interlayer layer dielectric (ILD) disposed over the gate structure; and
a gate contact penetrating through the ILD to land on the gate structure in the first or the second circuit area.

11. The semiconductor structure of claim 1, further comprising:
an isolation structure over the substrate and surrounding the first active regions, the second active regions, and the filter fins,
wherein the isolation structure has a greater thickness in the first and the second circuit areas than in the gate connector area.

12. A semiconductor structure, comprising:
a transistor area having active regions extending lengthwise along a first direction over a substrate, each of the active regions includes channel regions between source/drain features;
a filter area adjacent the transistor area along a second direction perpendicular to the first direction, the filter area having filter fins extending lengthwise along the first direction over the substrate; and
a gate structure having a gate dielectric and a gate fill metal over the gate dielectric, the gate structure extends across the transistor area and the filter area along the second direction, and the gate structure is disposed directly over the channel regions of the active regions and directly over the filter fins,
wherein the gate fill metal in the transistor area is different from the gate fill metal in the filter area.

13. The semiconductor structure of claim 12, wherein the gate fill metal in the filter area has a higher electrical resistance than the gate fill metal in the transistor area.

14. The semiconductor structure of claim 12, wherein the source/drain features of the active regions span a greater width than a width of the filter fins.

15. The semiconductor structure of claim 12, further comprising:
a first interlayer dielectric (ILD) layer surrounding the filter fins; and
a second interlayer ILD layer surrounding the source/drain features of the active regions, wherein the first ILD layer has a higher dielectric constant than the second ILD layer.

16. The semiconductor structure of claim 15, wherein the first ILD layer includes a metal oxide and the second ILD layer includes silicon oxide.

17. The semiconductor structure of claim 12, wherein the channel regions are doped with a first-type dopant, and the filter fins are doped with a second-type dopant opposite the first-type dopant.

18. A semiconductor structure, comprising:
a transistor region having active regions extending lengthwise along a first direction over a substrate, each of the active regions includes channel regions between source/drain features;
a filter region adjacent the transistor region along a second direction perpendicular to the first direction, the filter region having filter fins extending lengthwise along the first direction over the substrate;
a first gate structure having a first gate dielectric and a first gate electrode over the first gate dielectric, the first gate structure extends across the transistor region and the filter region along the second direction, and the first gate structure is disposed over a first set of channel regions and filter fins; and
a second gate structure having a second gate dielectric and a second gate electrode over the second gate dielectric, the second gate structure extends across the transistor region and the filter region along the second direction, and the second gate structure is disposed over a second set of channel regions and filter fins,
wherein a spacing between adjacent filter fins is smaller than a spacing between adjacent active regions.

19. The semiconductor structure of claim 18,
wherein the first and the second gate structures have a greater width in the filter region than in the transistor region,
wherein the first gate structure is electrically connected to a gate voltage, and the second gate structure is electrically connected to ground.

20. The semiconductor structure of claim 18, further comprising:
an interlayer dielectric (ILD) layer having a first dielectric portion surrounding the source/drain features, a second dielectric portion surrounding the filter fins; and
a metal feature between the first and the second gate structures along the first direction, the metal feature landing on the second dielectric portion of the ILD layer.
